(19) United States
(12) Patent Application Publication
(10) Pub. No.: US 2003/0063455 A1
(43) Pub. Date: Apr. 3, 2003

(54) Plug-in type CPU card reinforcement rack

(75) Inventor: Chih-Chung Chen, Taipei (TW)

Correspondence Address: DOUGHERTY & TROXELL, SUITE 1404, 5205 LEESBURG PIKE, FALLS CHURCH, VA, 22041, US

(73) Assignee: PORTWELL INC.

(21) Appl. No.: 09/968,860

(22) Filed: Oct. 3, 2001

(51) Int. Cl. H05K 7/14; H05K 7/18; H02B 1/01

(52) U.S. Cl. 361/829

(57) ABSTRACT

A reinforcement rack for a plug-in type CPU card, provided with a folded edge to lock into a longer side of the plug-in type CPU card and the other edge secured to said plug-in type CPU card for the purpose to bear heavier electronic devices without deformation and to avoid damaging any plug-in pins or slots.

### BACKGROUND OF THE INVENTION

(a) Field of the Invention

The present invention relates to a reinforcement rack for a plug-in type CPU card, and more particularly to a reinforcement rack applied to a full-size plug-in type CPU card (338 mm long), which can be mounted to one side of a full-length plug-in type CPU card opposite to the other side provided with plug-in pins, in order to improve bending strength of said plug-in type CPU card, so as to prevent any risk from possible breakage to the plug-in type CPU card during transportation or installation, and poor contact due to stripping or loosening any soldering point of electronic parts on the CPU card.

(b) Description of the Prior Art

The commercial and industrial computers today are under rapid and fast development. The speed of a core mechanism (so-called CPU) of a computer for data processing is nowadays amazingly high. For example, the latest Pentium 4 supplied by Intel when compared to a conventional CPU or Pentium III needs to use a larger heat sink and a larger fan (usually they are fixed to the heat sink) when said CPU is installed behind the plug-in type CPU card. Therefore, it is foreseeable that in future the heat sink and fan could be remarkably larger and heavier. Referring to FIGS. 1 and 2 of the accompanying drawings, said plug-in type CPU card 10 is like an interface card vertically plugged into the slots 22 of a passive back plane 21 in a case 20. However, the Pentium II, Pentium III or the current available Pentium 4 series of microprocessors (not illustrated) should be fixed onto the plug-in type CPU card 10 and get contact with the base 11 of a heat sink. Fins 111 are provided on the base 11 of the heat sink and said base 11 in the plug-in type CPU card 10 is arranged in parallel with the passive back plane 21. Since a fan (not illustrated) may be fixed onto said heat sink fins 111 to create a bending moment upon the plug-in type CPU card 10 resulting in that the weight of said plug-in type CPU card could be significantly leaned to either side. As the plug-in type CPU card 10 is fixed essentially from the clamping force by plug-in plugs 12 and the slots 22, one side of said plug-in type CPU card 10 is subject to be fixed by a guide way 23 in the case 20. A blanket 13 on the other side of said plug-in type CPU card 10 can be fixed with screws to the peripheral of a through hole 24 on the side of the case 20. Excessive weight of the heat sink and the fan often force the full-length plug-in type CPU card 10 to create a flexure, resulting in possible breakage to the conduction circuit distributed on said plug-in type CPU card 10, or broken plug-in type CPU card 10. Deformed CUP card could cause poor contact due to stripping or loosening soldering points on those electronic parts attached to the CPU card, resulting in malfunction of a computer. Furthermore, when a computer is under service or replacement, it would prevent from a freely access to remove the plug-in type CPU card 10 from the slots 22 or insert it into the slots 22, thus resulting possible damage to the slots 22 and affecting the good connection of the conductive contacts.

### SUMMARY OF THE INVENTION

In view of the abovementioned drawbacks, it is an object of the present invention to provide a reinforcement rack for a full-length plug-in type CPU card to solve the said problem. To achieve this purpose, said rack can be provided with a folded edge; one or more locking holes on one side of the rack, and one end of a locking member passes through a hole pre-bored on the longer side of said plug-in type CPU card corresponding to said locking hole, thus it can fix the said rack firmly to the plug-in type CPU card enabling to sustain heavier electronic devices without deformation.

### BRIEF DESCRIPTION OF THE DRAWINGS

Other objects, advantages, and novel features of the invention will become more apparent from the following detailed description when taken in conjunction with the accompanying drawings.

FIG. 1 is a schematic drawing showing a prior art of a plug-in type CPU card provided inside a case of a computer.

FIG. 2 is a perspective drawing of a preferred embodiment of the present invention secured in a plug-in type CPU card.

FIG. 3 is an exploded drawing of the preferred embodiment of the present invention secured in a plug-in type CPU card.

FIG. 4 is an exploded drawing showing that the preferred embodiment of the present invention is about to being plugged into the case of the computer.

FIG. 5 is a drawing showing the preferred embodiment is plugged into the case of the computer.

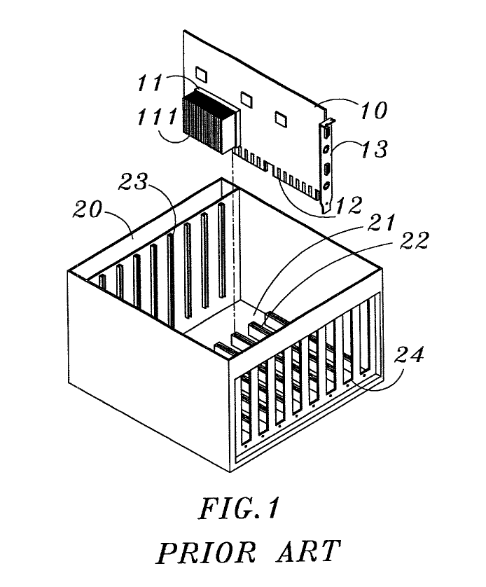

### DETAILED DESCRIPTION OF THE PREFERRED EMBODIMENTS

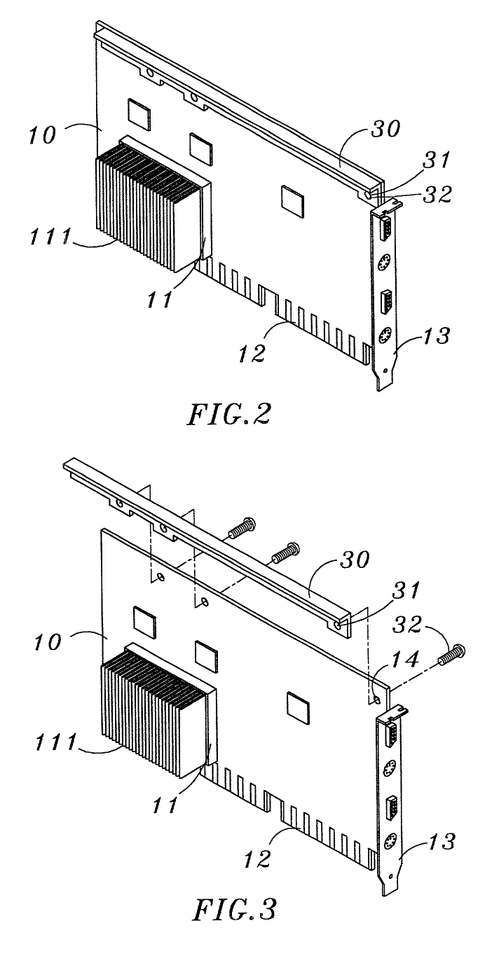

Referring to FIGS. 2 and 3, the present invention relates to a reinforcement rack for a plug-in type CPU card, and more particularly, to one that can be applied to a full-length plug-in type CPU card. The reinforcement rack 30 is an angle rack disclosed in a preferred embodiment of the present invention (however, said reinforcement rack may be substituted with other device for those who are familiar with the art of this invention). One or more locking holes 31 (a screw hole in the preferred embodiment) is or are bored in said reinforcement rack 30. One end of a locking member 32 (a screw in the preferred embodiment) passes through a corresponding hole 14 pre-bored on the longer side of said plug-in type CPU card 10 to secure said reinforcement rack 30 to said hole 14 on the plug-in type CPU card to sustain a heavier electronic device, e.g. a larger heat sink base 11 fixed to the CPU card 10 in the preferred embodiment. One end of said heat sink base 11 contacts a Pentium II, III or Pentium 4 microprocessor, which is fixed to the plug-in type CPU card 10, in order to significantly reduce the risk of deformation for the plug-in type CPU card 10.

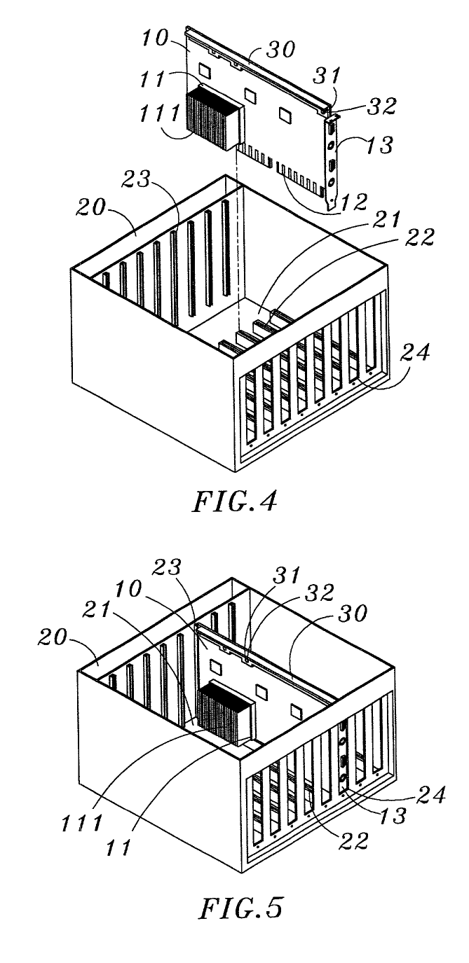

Now referring to FIG. 4, once the reinforcement rack 30 is secured in the plug-in type CPU card, the rack may be held by a hand to align the plug-in pins 12 (generally known as golden finger) of the plug-in type CPU card 10 at the slots 22 of a passive back plane 21 in a case 20, thus for one end of said plug-in type CPU card to slide into a guide way 23 of the case 20. In turn, said plug-in pins 12 of the plug-in type CPU card 10 is plugged into the slots 22 of the passive back plane 21 to complete conductive connection. Said plug-in type CPU card 10 is fixed by forces coming from three sources: clamping force by the plug-in pins 12 and the slots 22; one side of the plug-in type CPU card is subject to fixed by the guide way 23 of the case 20; and a blanket 13 on the other end of the plug-in type CPU card is locked to the peripheral of a through hole 24 provided on a side of the case 20 as illustrated in FIG. 5.

According to the above description, it is appreciated that when a computer is under service or replacement, the reinforcement rack 30 may be held by hand to facilitate removal or plugging the plug-in type CPU card from or into the slots 22 to avoid damaging the plug-in pins 12 or the slots 22.

What is claimed is:

1. A reinforcement rack applied to a full-length plug-in type CPU card, comprising of a folded edge, one or more locking holes bored on one side of the rack and one end of a locking member passing through a corresponding hole pre-bored on a longer side of the plug-in type CPU card to secure the rack to the plug-in type CPU card; whereby when the rack is held by hand, it can facilitate the removal or insertion of a plug-in type CPU card from or into the slots on a passive back plane in a case of the computer to significantly improve bending strength of a plug-in type CPU card.
